(19) United States
(12) Patent Application Publication
(10) Pub. No.: US 2006/0215437 A1
(43) Pub. Date: Sep. 28, 2006

(54) Recovering from memory imprints

(76) Inventors: Sanjeev N. Trika, Hillsboro, OR (US); John I. Garney, Portland, OR (US); Robert Royer JR., Portland, OR (US)

Correspondence Address: TROP PRUNER & HU, PC, 1616 S. VOSS ROAD, SUITE 750, HOUSTON, TX, 77057-2631, US

(21) Appl. No.: 11/091,164

(22) Filed: Mar. 28, 2005

(51) Int. Cl. G11C 11/22

(52) U.S. Cl. 365/145

(57) ABSTRACT

Memory cells, such as polymer memory cells, that are prone to imprinting, may be refreshed. In addition, if despite periodic refreshing, the cells become imprinted anyway, this may be detected and counter measures taken to prevent adverse consequences.

### BACKGROUND

This invention relates generally to semiconductor memories and, particularly, to such memories which are prone to imprinting.

Memory imprinting is when a memory cell retains its programmed state and cannot be readily programmed to a different state. A memory cell is a collection of one or more memory bits. Memory imprinting is a function of the amount of time between memory accesses. When the time between accesses is sufficiently long, some memories, such as polymer memories, retain the programmed state unless handled specially.

When a memory cell is imprinted or stuck, a slower access timing unimprinting protocol may overcome the imprinting. A higher voltage or allowing the voltage to act on the cell for a longer time may also overcome the imprint.

One problem with overcoming imprinting is that it must be known in advance whether or not a given cell is imprinted. If the cell that is imprinted is accessed normally, the information that is stored in the cell may be destroyed. Conversely, if all of the cells are accessed with the unimprinting protocol, the access time and the performance of the memory may be severely degraded, and/or endurance of the memory cells may be significantly reduced.

Thus, there is a need for better ways to deal with imprinted memory cells.

### BRIEF DESCRIPTION OF THE DRAWINGS

FIG. 1 is a schematic depiction of a system in accordance with one embodiment of the present invention;

FIG. 2 is a flow chart for software in accordance with one embodiment of the present invention;

FIG. 3 is a flow chart for software in accordance with one embodiment of the present invention; and

FIG. 4 is a flow chart for software in accordance with one embodiment of the present invention.

### DETAILED DESCRIPTION

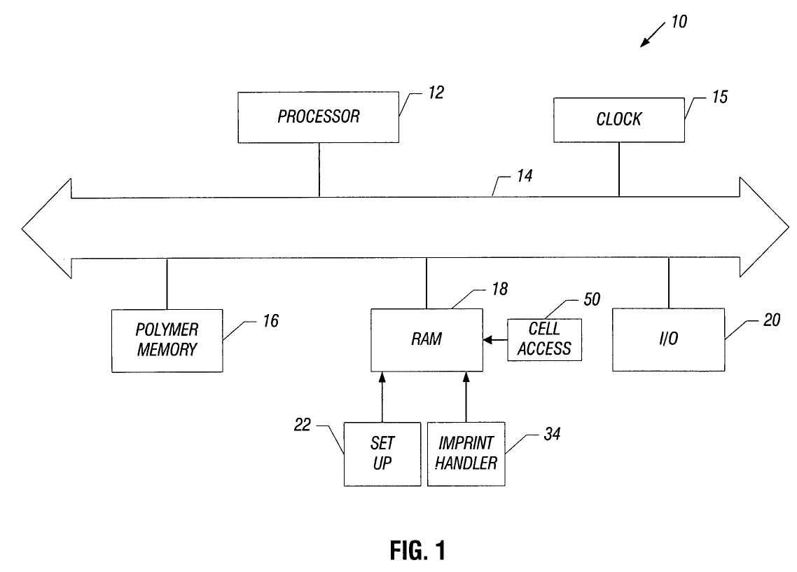

Referring to FIG. 1, a processor-based system 10 may be any processor-based system, such as a computer, a laptop computer, a personal digital assistant, a cellular telephone, a pager, a game, or a set top box, to mention a few examples. The processor-based system 10 may include a processor 12 which may be a multipurpose processor, an embedded processor, such as a microcontroller, or even a digital signal processor. The processor 12 may communicate with other components over a bus 14.

Those other components may include a semiconductor memory 16 which may be prone to stuck or imprinted cells, such as a polymer memory. Other memories that are subject to these problems may be used as well.

A random access memory 18 is also coupled to the bus 14. The random access memory 18 may store an imprint handler software 34, handler set up software 22, and cell access software 50. The random access memory 18 may, for example, be a semiconductor memory or a rotating memory such as a hard disk drive or a digital versatile disk (DVD) drive, or any other randomly accessible memory.

Also coupled to the bus 14 may be an input/output device 20 which may be any of the conventional input/output devices including a display, a keyboard, or a mouse, to mention a few examples. Finally, a system clock 15 (or a clock interface to obtain timing information from an external source) is provided. However, other components may be utilized in addition to or in place of the components depicted in FIG. 1.

In some embodiments, the memory 16 may be a disk cache formed by a polymer memory. The memory 16 may store data within layers. The higher the number of layers, the higher the capacity of the memory. Each layer may include polymer chains with dipole moments. Data may be stored by changing the polarization of polymer between conductive lines.

In various situations, the memory 16 may become imprinted such that if accessed with normal access timings and/or voltage, imprinted memory cells may be destroyed. In order to combat the effects of imprinting, two different approaches may be implemented in some embodiments of the present invention. One approach is to periodically refresh the memory 16 to prevent imprinting from occurring in the first place. The other approach is to compensate for imprinting in those cases where imprinting occurred or likely may have occurred, regardless of the use of preventive measures such as refreshing. Imprinting may occur when a system has been shut-off for a long time, or when a system failure occurs, a power loss occurs, or some other unavoidable circumstance results.

Each cell in the memory 16 may be associated with metadata which indicates various information which may be maintained for that cell. In addition to various other information, the bIMPRINT data about whether the memory cell is likely to have been imprinted may also be stored.

The metadata may be stored in a virtual memory, in the memory 16, or in the memory 18, as examples. The metadata may be stored as packed metadata in a single memory block for all the various blocks or it may be stored in association with each cache line, as another example. Any of a variety of techniques for storing the metadata indicating whether or not a given cell is imprinted may be used. In addition, instead of maintaining the imprint information on a cell-by-cell basis, it may be stored in association with other memory units including blocks, words, arrays, or other arrangements.

In addition, some embodiments decrease the likelihood that imprinting may occur by using a refresh cycle on a periodic basis. The refreshing feature may be ineffective where the system is shutdown for long periods.

To implement these imprinting compensation techniques, the imprint handler software 34, the cell access software 50 and the setup software 22 may be stored in the randomly accessible memory 18 or in some other system memory.

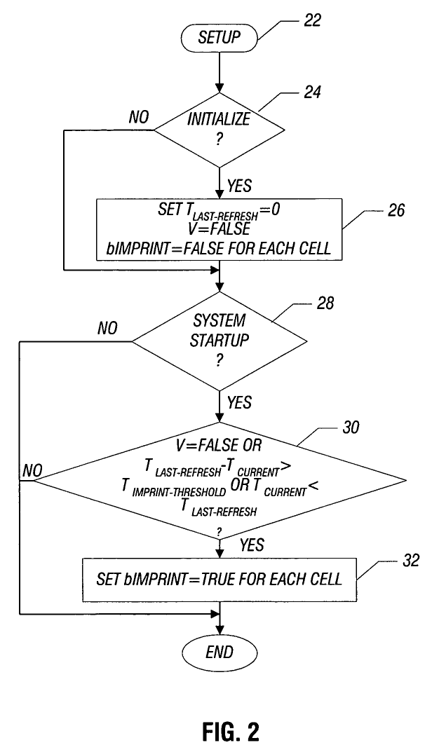

Referring to FIG. 2, the setup software 22 sets up for the operation of the imprint handler software 34. Initially, a check at diamond 24 indicates whether an initialization cycle is being undertaken. If so, a variable called T_{last-refresh} may be set equal to zero and another variable V may be set equal to false. Finally, bIMPRINT for each cell is set equal to false for each memory cell in all copies of the metadata, in some embodiments, as indicated in block 26.

Then, a check at diamond 28 determines whether a system startup has occurred. A system startup may occur in the case of a system boot, after a shutdown, crash or a power failure, as three examples. If a system startup is detected at diamond 28, a check at diamond 30 determines whether any of three circumstances have arisen. The first circumstance is that the variable V is equal to false. The variable V is a variable that indicates whether the time stamp variable T_{last-refresh} is valid. Generally, it will be valid unless the memory has never been refreshed. The next item that is checked is whether the current time T_{current} minus the variable T_{last-refresh} is greater than a variable T_{imprint-threshold.} The variable T_{imprint-threshold} is the time between refreshes threshold for when imprinting will likely occur absent an intervening refresh. That threshold may be specified in terms of a time which may be sufficient to cause imprinting to occur in the particular memory 16 involved. The final item that is checked is whether the variable T_{current}, indicating the current time, is less than the variable T_{last-refresh}, which would indicate some type of error situation.

If any of these three circumstances is found to exist in diamond 30, in one embodiment, then the imprint bit (bIMPRINT) associated with each memory cell may be set equal to true as indicated at 32.

The cell access software 50 implements the two compensation techniques, those being to prevent imprinting from occurring and to detect and compensate for imprinting when it likely has already occurred nonetheless.

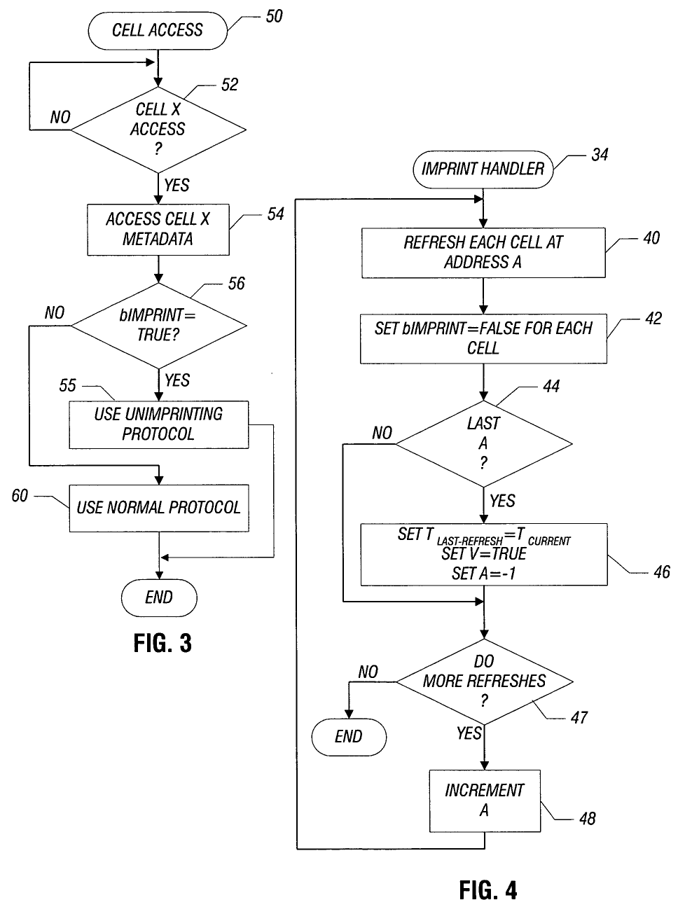

Referring to FIG. 3, the cell access software 50 begins by determining, at diamond 52, whether a cell is being accessed. Next the metadata for that cell is accessed (block 54). At diamond 56, the flow determines whether the variable bIMPRINT is true. If so, each of the cells with a true bIMPRINT variable may be subsequently accessed using the unimprinting protocol as indicated in block 55. In one embodiment, each of the cells may be successively accessed slowly in order to undo any potential imprinting. This may involve reading the data as stored in the cell and writing it back using relatively slow timing to avoid upsetting the data stored therein. Another embodiment is simply to require that the next normal access use slow timing and that thereafter that particular cell be marked as being no longer imprinted. In either case, a slower access protocol is implemented, as indicated in block 38. If bIMPRINT is not true the normal access protocol is used.

Referring to FIG. 4, if no imprinting was detected at diamond 56, each of the cells may be refreshed starting at an address A as indicated in block 40. A is a variable which holds the next address to be refreshed. The bIMPRINT variable is then set equal to false for each cell as it is refreshed. A check at diamond 44 determines whether the last cell has been refreshed and the flow continues until the last cell is refreshed.

After the last cell has been refreshed, as determined at diamond 44, the variable T_{last-refresh} is set equal to the current time. The current time may be accessed from the system time clock 15 or from an external time device via a clock interface as indicated in block 46. The variable V is set equal to true and the variable A is set equal to −1. A check at diamond 47 determines whether there are more refreshes to do. If so, in block 48, the variable A is incremented and the flow recycles.

A number of variations may be implemented. The memory 16 may be refreshed on each boot/resume cycle. This refresh scheme obviates the need for the variable T_{last-refresh}, the variable V, or bIMPRINTED states. However, in some embodiments, this may significantly impact the boot/resume performance for realistically sized non-volatile memories and unimprint protocols.

In other embodiments, the cell V may be omitted by simply setting T_{last-refresh} to the minimum possible time each time the logic calls for the variable V to be set equal to FALSE. Also, the memory cells need not be refreshed in order. Some types of memories have segments or collections of memory cells that lock out for some time after access. A striding pattern of accesses in the memory refresh loop may be more appropriate in such cases. In addition, memory cells may be refreshed in blocks. Thus, it may be desirable to refresh N memory cells at a time in parallel or in sequence. These N cells need not be contiguous and multiple counters may be maintained to track each cell range that has been refreshed. N may also vary depending on other system variables, including whether the system is running on line power, in which case it may be preferred to refresh the memory in larger blocks.

In some embodiments, a history may be maintained for each memory cell to decide when the cell was last refreshed. In its simplistic form, a time stamp can be kept per memory cell or memory block in some embodiments. This may reduce the number of refreshes done at the expense of keeping more data per memory cell.

An initial bit R can be maintained, in one embodiment, per memory cell (in its volatile metadata), that specifies whether a given cell has already been refreshed since the previous time based refresh because of an unrelated memory access. These R bits may be initialized to zero at system startup and set to one on every access. During the refresh loop, an address A is refreshed in non-volatile memory only if its R bit is zero and irrespective, the R bit for the memory cell is cleared.

In some embodiments, imprints may be avoided or, if they occur nonetheless, recovery may be provided without accessing all cells on slow timing. Thus, in some embodiments, imprinting may be reduced and access times increased.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
refreshing memory cells prone to imprinting.

2. The method of claim 1 including associating metadata with said memory cells to indicate whether or not those cells are likely to be imprinted.

3. The method of claim 2 including associating metadata with a group of cells.

4. The method of claim 1 including determining whether a cell may have been imprinted and, if so, scheduling said cell for a slower access.

5. The method of claim 4 including reading the contents of said cell and writing the contents back.

6. The method of claim 4 including waiting for a request to access the cell that may be imprinted and at such time implementing said slower access.

7. The method of claim 1 including periodically refreshing said cells prone to imprinting.

8. The method of claim 1 including comparing the amount of time between refreshes with a threshold indicative of whether imprinting is likely to occur.

9. The method of claim 8 including treating a normal cell access as a refresh, thereby reducing the number of refreshes to a cell.

10. The method of claim 1 including refreshing memory cells on each boot/resume cycle.

11. The method of claim 1 including refreshing the memory cells in blocks.

12. The method of claim 1 including maintaining a refresh history for memory cells.

13. An article comprising a medium storing instructions that, if executed, enable a processor-based system to refresh memory cells prone to imprinting.

14. The article of claim 13 further storing instructions that, if executed, enable the processor-based system to refresh said memory cells at periodic intervals.

15. The article of claim 13 further storing instructions that, if executed, enable metadata to be associated with memory cells to indicate whether or not those cells are likely to be imprinted.

16. The article of claim 15 further storing instructions that, if executed, enable the processor-based system to associate metadata with each cell.

17. The article of claim 16 further storing instructions that, if executed, enable metadata to be associated with a group of cells.

18. The article of claim 13 further storing instructions that, if executed, enable the processor-based system to determine whether a cell may have been imprinted and, if so, schedule said cell for a slower access.

19. The article of claim 18 further storing instructions that, if executed, enable the processor-based system to read the contents of said cell and write the contents back to said cell.

20. The article of claim 19 further storing instructions that, if executed, enable the processor-based system to wait for a request to access the cell that may be imprinted and at such time implement said access on a slower basis.

21. The article of claim 13 further storing instructions that, if executed, enable the processor-based system to compare the amount of time between refreshes with a threshold indicative of whether imprinting is likely to occur.

22. A system comprising:
a processor;
a clock interface coupled to said processor; and
a random access memory storing instructions that, if executed, enable the processor-based system to refresh memory cells prone to imprinting.

23. The system of claim 22 wherein said random access memory stores instructions that, if executed, enable the system to periodically refresh said memory cells.

24. The system of claim 22 wherein said random access memory stores instructions that, if executed, enable metadata to be associated with cells in said memory cells to indicate whether or not those cells are likely to be imprinted.

25. The system of claim 22 wherein said random access memory stores instructions that, if executed, enable the processor-based system to determine whether a cell may have been imprinted and, if so, schedule said cell for a slower access.

26. The system of claim 25 wherein said random access memory stores instructions that, if executed, enable the processor-based system to read the contents of said cell and write the contents back to said cell.

27. The system of claim 26 wherein said random access memory stores instructions that, if executed, enable the processor-based system to wait for a request to access the cell that may be imprinted and at such time implement said access on a slower basis.

28. The system of claim 22 wherein said random access memory stores instructions that, if executed, enable the processor-based system to compare the amount of time between refreshes with a threshold indicative of whether imprinting is likely to occur.
